(19) United States
(12) Patent Application Publication
(10) Pub. No.: US 2009/0149016 A1
(43) Pub. Date: Jun. 11, 2009

(54) SEMICONDUCTOR DEVICE AND METHOD OF FABRICATING THE SAME

(75) Inventors: Jin-Woo PARK, Chungcheongnam-do (KR); Tae-Joo HWANG, Gyeonggi-do (KR); Nam-Seog KIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/330,416

(22) Filed: Dec. 8, 2008

(30) Foreign Application Priority Data
Dec. 6, 2007 (KR) 10-2007-0126386

(51) Int. Cl. H01L 21/768

(52) U.S. Cl. 438/614; 438/613; 257/E21.582

(57) ABSTRACT

Provided is a semiconductor device and a method of fabricating the same. The method of fabricating the semiconductor device includes forming a mask pattern having an opening corresponding to an electrode pad formed on a semiconductor substrate; forming a bump by filling the opening with a conductive first material; forming a sidewall film on sidewalls of the bump using a second material; forming a connection member between an upper surface of the bump and a wire substrate using a conductive third material in order to electrically connect the bump and the wire substrate; and forming an underfill resin between the wire substrate and the semiconductor substrate, wherein a wetting angle between the second material and the third material is greater than that between the first material and the third material.

### CROSS-REFERENCE TO RELATED PATENT APPLICATION

This application claims priority under 35 U.S.C. §119 to Korean Patent Application No. 10-2007-0126386, filed on Dec. 6, 2007 in the Korean Intellectual Property Office, the disclosure of which is incorporated herein in its entirety by reference.

### BACKGROUND

The present inventive concept relates to a semiconductor device and a method of fabricating the same. More particularly, the present inventive concept relates to a semiconductor device that can maintain a desired stand-off height in a semiconductor package that uses a bump structure and a method of fabricating the same.

### SUMMARY

The present inventive concept provides a semiconductor device having solder connections that are prevented from contacting sidewalls of bumps while a bonding force with an underfill resin is improved.

The present inventive concept also provides a method of fabricating a semiconductor device having solder connections that are prevented from contacting sidewalls of bumps while a bonding force with an underfill resin is improved.

According to an aspect of the present inventive concept, there is provided a method of fabricating a semiconductor device comprising: forming a mask pattern having an opening on a semiconductor substrate corresponding to an electrode pad formed on the semiconductor substrate; forming a bump on the electrode pad by filling the opening with a conductive first material; forming a sidewall film on sidewalls of the bump using a second material; forming a connection member using a conductive third material between an upper surface of the bump and a wire substrate to electrically connect the bump and the wire substrate; and forming an underfill resin between the wire substrate and the semiconductor substrate.

According to another aspect of the present inventive concept, there is provided a method of fabricating a semiconductor device comprising: forming a mask pattern having an opening on a semiconductor substrate corresponding to an electrode pad formed on the semiconductor substrate; forming a sidewall film using a second material on inner walls of the mask pattern that defines the opening; forming a bump by filling the opening with a conductive first material; removing the mask pattern; forming a connection member using a conductive third material between an upper surface of the bump and a wire substrate to electrically connect the bump and the wire substrate; and forming an underfill resin between the wire substrate and the semiconductor substrate, wherein a wetting angle between the second material and the third material is greater than that between the first material and the third material.

According to yet another aspect of the present inventive concept, there is provided a method of fabricating a semiconductor device comprising: forming a mask pattern defining an opening on a semiconductor substrate, the opening corresponding to an electrode pad formed on the semiconductor substrate; forming a bump on the electrode pad by filling the opening with a first material; removing the mask pattern; forming a sidewall film on sidewalls of the bump using a second material; forming a top film on an upper surface of the bump using a fourth material; and forming a connection member between the top film and a wire substrate using a third material so as to electrically connect the bump and the wire substrate; wherein a wetting angle between the second material and the third material is greater than a wetting angle between the fourth material and the third material.

### BRIEF DESCRIPTION OF THE DRAWINGS

The above and other features and advantages of the present inventive concept will become more apparent by describing in detail exemplary embodiments thereof with reference to the attached drawings in which:

FIG. 1 is a cross-sectional view of a semiconductor device according to an embodiment of the present inventive concept;

FIG. 2 is a cross-sectional view of a semiconductor device according to another embodiment of the present inventive concept;

FIGS. 3A through 3C are cross-sectional views illustrating an angle formed between a solid surface and a free surface of a liquid, that is, a wetting angle θ;

FIGS. 4A through 4F are cross-sectional views illustrating a method of fabricating the semiconductor device of FIG. 1, according to an embodiment of the present inventive concept;

FIGS. 5A and 5E are cross-sectional views illustrating a method of fabricating the semiconductor device of FIG. 1, according to another embodiment of the present inventive concept;

FIGS. 6A and 6F are cross-sectional views illustrating a method of fabricating the semiconductor device of FIG. 2, according to yet another embodiment of the present inventive concept;

FIG. 7 is a schematic drawing illustrating the roughness of CuO formed on a Cu thin film; and

FIG. 8 is a scanning electron microscope (SEM) image of a surface of a CuO film formed according to an embodiment of the present inventive concept.

### DETAILED DESCRIPTION

The present inventive concept will now be described more fully with reference to the accompanying drawings, in which exemplary embodiments of the inventive concept are shown. The present inventive concept may, however, be embodied in many different forms and should not be construed as limited to the exemplary embodiments set forth herein. Rather, these embodiments are provided so that this disclosure will be thorough and complete, and will fully convey the scope of the inventive concept to those skilled in the art. In the drawings, lengths and sizes of layers and regions may be exaggerated for clarity.

Like reference numerals in the drawings denote like elements, and thus their description will be omitted. It will also be understood that when a layer is referred to as being “on” another layer or substrate, it can be directly on the other layer or substrate, or intervening layers may also be present. Also, spatially relative terms, such as “below” or “lower” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” other elements or features would then be oriented “above” the other elements or features. Thus, the exemplary term “below” can encompass both an orientation of above and below.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section.

FIG. 1 is a cross-sectional view of a semiconductor device 100 according to an embodiment of the present inventive concept.

Referring to FIG. 1, the semiconductor device 100 includes an electrode pad 25 on a semiconductor substrate 20. The electrode pad 25 may be formed of aluminum (Al). A first protective film 30 and/or a second protective film 40 that expose the electrode pad 25 may further be formed on the semiconductor substrate 20. The first protective film 30 and the second protective film 40 may respectively be formed of an oxide film and a nitride film.

A bump 80, formed of a conductive first material such as copper (Cu), is formed on the electrode pad 25. The bump 80 may also be formed of a Cu alloy, Nickel (Ni), and/or a Ni alloy, and may have a pillar shape.

First and second intermediate connection films 50a and 60a formed of titanium (Ti) and/or Cu may be interposed between the electrode pad 25 and the bump 80. The first intermediate connection film 50a may be formed of Ti and the second intermediate connection film 60a may be formed of Cu, but the present inventive concept is not limited thereto.

The bump 80 is electrically connected to external circuitry through a wire substrate 130. A connection member 120c formed of a conductive third material may be interposed between the bump 80 and the wire substrate 130. The wire substrate 130 may be, for example, a printed circuit board (PCB) and the conductive third material used to form the connection member 120c may be solder. The term solder generally denotes a Sn/Pb alloy, but may also denote a Sn/Ag alloy, a Sn/Cu alloy, a Sn/Zn alloy, or an alloy of Sn and another material, among other things. An underfill resin 150 is filled in a space between the semiconductor substrate 20 and the wire substrate 130.

The connection member 120c may be formed on an upper surface of the bump 80. If the connection member 120c extends to sidewalls of the bump 80, a distance between the upper surface of the bump 80 and the wire substrate 130 can be reduced. In this case, it is difficult to fill the underfill resin 150 in the space between the semiconductor substrate 20 and the wire substrate 130, and as a result, the semiconductor device 100 may be weak when exposed to external impact.

The connection member 120c can be formed such that, after coating a first solder layer on the upper surface of the bump 80 and coating a second solder layer on a lower surface of the wire substrate 130, the bump 80 and the wire substrate 130 are reflowed and compressed to form the connection member 120c. However, the upper surface and the sidewalls of the bump 80 are Cu surfaces, and thus, it is thermodynamically likely that the connection member 120c will be formed on the sidewalls of the bump 80, instead of solely on the top surface of the bump 80. Thus, it is desirable to appropriately treat the sidewalls of the bump 80 so that the sidewalls of the bump 80 have a lower wettability than that of the upper surface of the bump 80. In other words, a wetting angle between the sidewalls of the bump 80 and the connection member 120c can be greater than that between the connection member 120c and the upper surface of the bump 80.

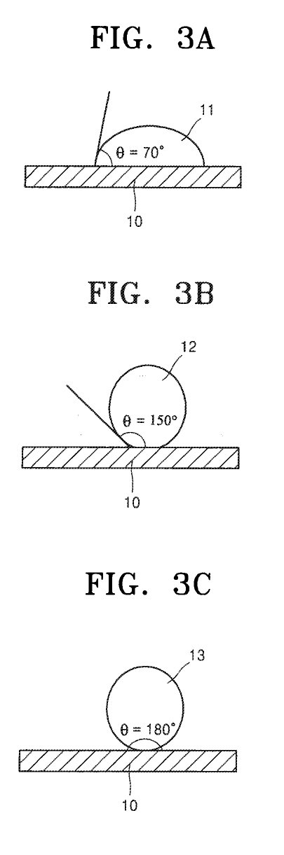

FIGS. 3A through 3C are cross-sectional views illustrating an angle formed between a solid surface and a free surface of a liquid, that is, a wetting angle θ.

Generally, a wetting angle θ denotes an angle formed between a surface of a solid and a free surface of a liquid when the liquid and the solid are placed in contact in thermodynamic equilibrium. The wetting angle θ is determined by an agglomeration force between liquid molecules and an adhesion power between the liquid and solid.

A wetting angle formed between a surface of a liquid and a solid indicates the wettability of the surface of the solid, and is mostly measured by using sessile liquid drops. A low wetting angle indicates a high wettability and a high surface energy and a high wetting angle indicates a low wettability and a low surface energy.

FIG. 3A is a cross-sectional view of an angle formed between a surface of a solid 10 and a free surface of a liquid 11, that is, a wetting angle θ of 70°.

FIG. 3B is a cross-sectional view of an angle formed between the surface of the solid 10 and a free surface of a liquid 12, that is, a wetting angle θ of 150°.

FIG. 3C is a cross-sectional view of an angle formed between the surface of the solid 10 and a free surface of a liquid 13, that is, a wetting angle θ of 180°.

Referring to FIGS. 3A to 3C, the case of FIG. 3A has the highest wettability between the solid and the liquid, and the case of FIG. 3C has the lowest wettability between the solid and the liquid, as shown by the different wetting angles θ.

Referring to FIG. 1 again, sidewall films 90 formed of a second material are formed on sidewalls of the bump 80. A wetting angle between the second material and the conductive third material used to form the connection member 120c can be larger than a wetting angle between the conductive third material and the conductive first material used to form the bump 80. Accordingly, the upper surface of the connection member 120c can have a wettability higher than that of sidewalls of the bump 80, and thus, it can be thermodynamically unlikely for the connection member 120c to be formed on sidewalls of the bump 80.

More specifically, an exemplary case in which the bump 80 is formed of Cu and the connection member 120c is formed of solder is described below.

If sidewall films 90 formed of CuO are formed on the sidewalls of the bump 80, the solder is only formed on the upper surface of the bump 80 and is not formed on the sidewalls of the bump 80. This result is obtained due to the wetting angle between the solder and Cu being smaller than that between the solder and the CuO.

The sidewall films 90 formed of CuO may be formed on the sidewalls of the bump 80 by plating a CuO film or by oxidizing Cu on the sidewalls of the bump 80.

In particular, in the copper oxide, the ratio of Cu:O may be greater than that of Cu₂O. The copper oxide may have a needle structure so that the sidewall films 90 formed of copper oxide have a rough surface at a microscopic level, and thus, may further increase an adhesion force with the underfill resin 150 in a subsequent process.

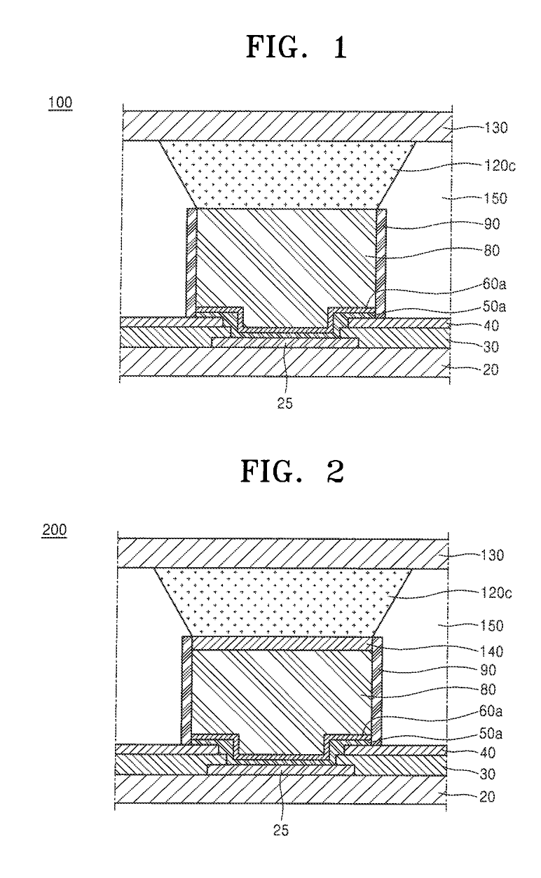

FIG. 2 is a cross-sectional view of a semiconductor device 200 according to another embodiment of the present inventive concept.

Like reference numerals are used to indicate substantially similar elements of FIG. 1, and thus, a description thereof will not be repeated.

The semiconductor device 200 according to another embodiment of the present inventive concept further includes a top film 140 formed of a fourth material on the upper surface of the bump 80. A wetting angle between the second material and the conductive third material can be greater than that between the conductive third material and the fourth material.

More specifically, an exemplary case in which the bump 80 is formed of Cu and the connection member 120c is formed of solder is described. The top film 140 is formed on the upper surface of the bump 80 using gold (Au). The top film 140 formed of Au has an adhesion force with the solder. If the sidewall films 90, formed of copper oxide, are formed on the sidewalls of the bump 80, the solder is only formed on the upper surface of the top film 140, and the solder is not formed on the sidewalls of the bump 80. This result is obtained due to the wetting angle between Au and solder being smaller than that between solder and copper oxide.

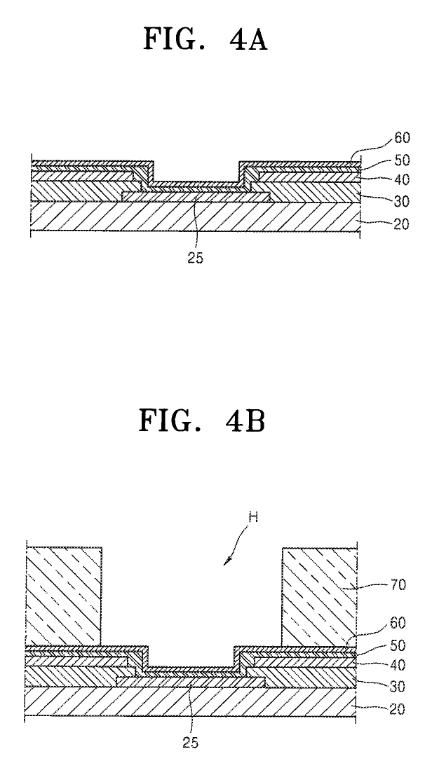

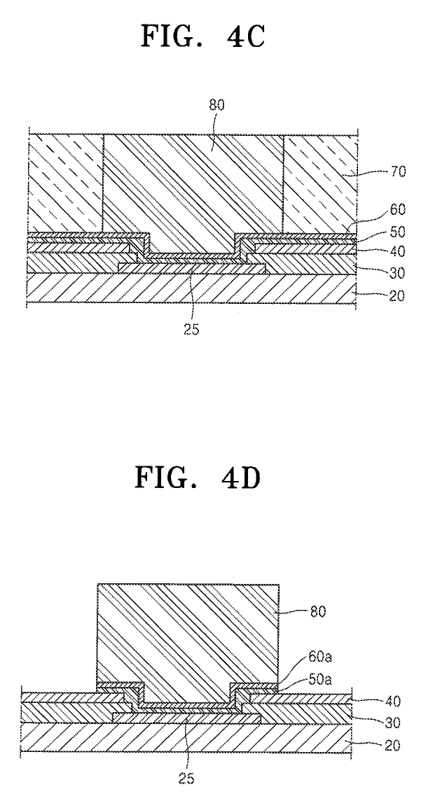

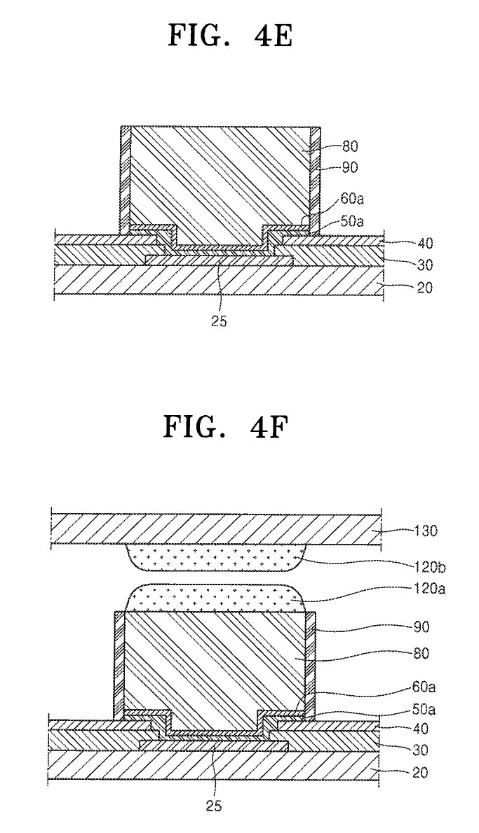

FIGS. 4A through 4F are cross-sectional views illustrating a method of fabricating the semiconductor device 100 of FIG. 1, according to an embodiment of the present inventive concept.

Referring to FIG. 4A, an electrode pad 25 formed of Al is formed on an upper surface of a semiconductor substrate 20. A first protective film 30 and/or a second protective film 40 that have an opening formed therein to expose the electrode pad 25 may further be formed on the semiconductor substrate 20. The first protective film 30 and/or the second protective film 40 respectively may be formed of an oxide film and/or a nitride film.

First and second intermediate connection films 50 and 60 formed of Ti and/or Cu may be formed on the electrode pad 25 so as to be interposed between the electrode pad 25 and the bump 80 (shown in FIG. 4C). The first intermediate connection film 50 may be formed of Ti and the second intermediate connection film 60 may be formed of Cu, but the present inventive concept is not limited thereto.

Referring to FIG. 4B, a mask pattern 70 having an opening H is formed on a location corresponding to the electrode pad 25. The mask pattern 70 may be a photoresist pattern.

Referring to FIG. 4C, the bump 80 is formed by filling the opening H defined by inner sidewalls of the mask pattern 70 with a conductive first material. For example, the conductive first material may include Cu. The bump 80 can be formed by electroplating and/or electroless plating. However, the bump 80 may also be formed using a conventional method of forming a metal film (for example, using a physical or chemical vapor deposition method) instead of the plating methods. The bump 80 may have a pillar shape.

Referring to FIG. 4D, after removing the mask pattern 70 by, for example, ashing, a second intermediate connection film pattern 60a and a first intermediate connection film pattern 50a are formed by respectively etching the second intermediate connection film 60 and the first intermediate connection film 50 using the bump 80 as a mask.

Referring to FIG. 4E, sidewall films 90 are formed on sidewalls of the bump 80 using a second material. If the bump 80 is formed of Cu, the sidewall films 90 formed of the second material may be copper oxide films.

Referring to FIG. 4F, to form a connection member 120c (refer to FIG. 1) formed of a third material between the bump 80 and a wire substrate 130, a first solder layer 120a is coated on an upper surface of the bump 80 and a second solder layer 120b is coated on a lower surface of the wire substrate 130. Afterwards, the first solder layer 120a and the second solder layer 120b are reflowed and compressed to form the connection member 120c. Next, a space between the semiconductor substrate 20 and the wire substrate 130 is filled with an underfill resin 150 (refer to FIG. 1).

Referring to FIG. 4E again, the second material may be selected so that a wetting angle between the second material and the third material is greater than that between the first material and the third material. In particular, the wetting angle between the first material and the third material may be less than 90°, and the wetting angle between the second material and the third material may be greater than 90°. For example, if the first material includes Cu and the third material includes solder, the second material may be a copper oxide.

The Cu oxide films 90 may be formed on the sidewalls of the Cu bump 80 by oxidizing the sidewalls of the Cu bump 80. A first method to oxidize the sidewalls of the Cu bump 80 is plasma treating the bump 80 under an oxygen atmosphere.

A second method to oxidize the sidewalls of the bump 80 is to sequentially perform a first operation in which the sidewalls of the bump 80 are soft etched in an atmosphere containing H₂SO₄ and H₂O₂ or an atmosphere containing sodium peroxosulphate (NaPS), and a second operation in which a copper oxide film having a ratio of Cu:O greater than that of Cu₂O is formed on the bump 80 by treating the sidewalls of the bump 80 using a basic solution containing hydroxide ions.

The first operation in which the surface of the bump 80 is soft etched can be employed to uniformly form a rough Cu surface by etching the surface of the bump 80 in an atmosphere containing H₂SO₄ and H₂O₂ or an atmosphere containing NaPS, which may be expressed by chemical equation 1 below.

Cu+H₂O₂→CuO+H₂O

CuO+H₂SO₄→CuSO₄+H₂O [Chemical equation 1]

A washing process for removing contaminants present on the surface of the Cu bump 80 may be performed prior to performing the soft etching of the surface of the bump 80.

A copper oxide film in which the ratio of Cu:O is greater than Cu₂O is formed on the bump 80 by treating the surface of the bump 80 on which the first operation was performed using a basic solution that includes hydroxide ions. More specifically, the above process is expressed by chemical equation 2 below.

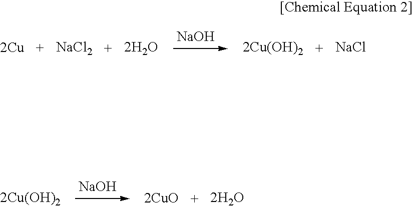

The relative ratio between Cu₂O and CuO, the crystal structure, and the formation speed may be controlled according to the concentration and temperature of the solution that includes the hydroxide ions. If the solution includes a relatively large amount of hydroxide ions, the ratio of Cu:O is greater than Cu₂O, and the CuO has a needle structure. In this case, the copper oxide film is black and has a density of about 0.4 mg/cm² or higher.

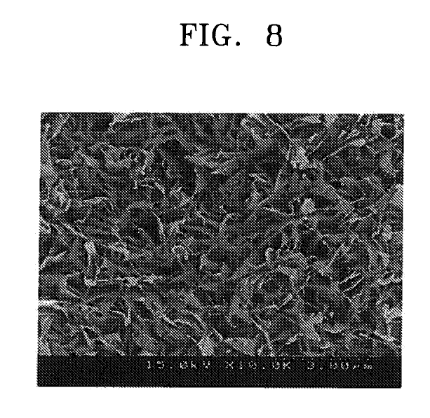

FIG. 7 is a schematic drawing illustrating roughness of CuO formed on a Cu thin film, and FIG. 8 is a scanning electron microscope (SEM) image of a surface of a CuO film formed according to an embodiment of the present inventive concept.

Referring to FIG. 7, CuO needles 90b are formed on the Cu thin film 90a.

Referring to FIG. 8, a surface of the CuO film formed according to an embodiment of the present inventive concept microscopically has a very rough surface since the ratio of Cu:O is greater than in Cu₂O.

Thus, the sidewall films 90 formed on the sidewalls of the bump 80 have a rough surface due to the higher ratio of Cu:O than Cu₂O, and thus, the underfill resin is strongly adhered with the sidewall films 90 formed on the sidewalls of the bump 80 in a subsequent process of filling the underfill resin.

After performing the second operation in which the CuO film having a ratio of Cu:O higher than that of Cu₂O is formed on the bump 80 by treating the bump 80 with a basic solution having hydroxide ions, a third operation in which the CuO film is reduced using Morpholine Borane may further be included in order to protect the CuO film from an acid or basic solution. The third operation may be expressed by chemical equation 3 below.

2CuO+R—BH₃→2Cu+R—BO₃ [Chemical equation 3]

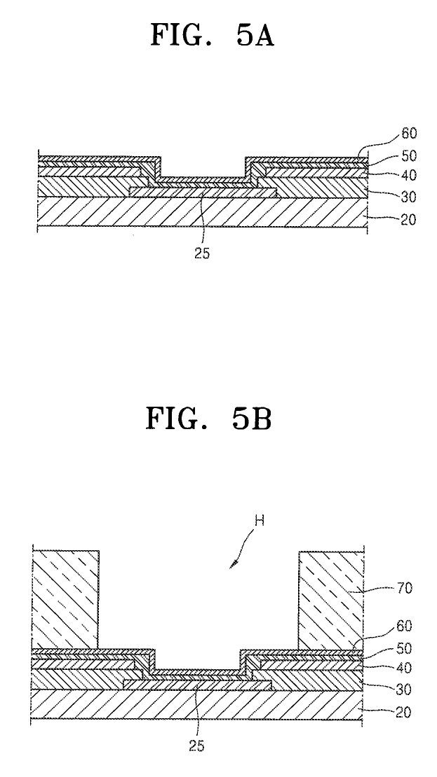

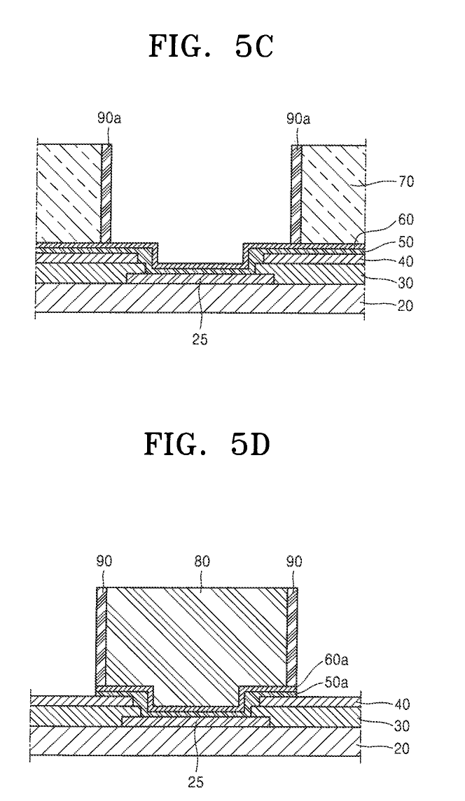

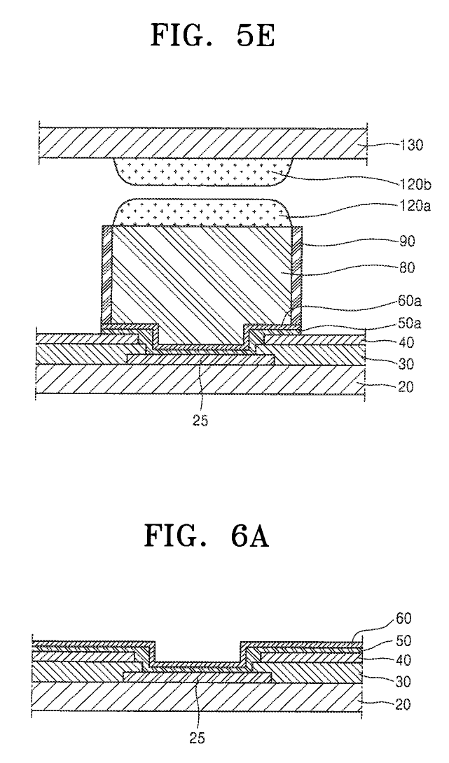

FIGS. 5A and 5E are cross-sectional views illustrating a method of fabricating the semiconductor device 100 of FIG. 1, according to another embodiment of the present inventive concept.

Like reference numeral are used to indicate substantially similar elements in the foregoing embodiments, and thus, a description thereof will not be repeated.

FIGS. 5A and 5B are similar to FIGS. 4A and 4B, and thus, the description thereof will not be repeated.

Referring to FIG. 5C, sidewall films 90a formed of a second material are formed on inner walls of a mask pattern 70 that defines an opening H. If a bump 80 is formed of Cu in a subsequent process, the second material may be a copper oxide. In this case, the sidewall films 90a formed of a copper oxide may be formed using a plating method.

Referring to FIG. 5D, the bump 80 is formed by filling the opening H with a conductive first material. The opening H is defined by the mask pattern 70 and the sidewall films 90a formed of the second material. Next, the mask pattern 70 is removed using, for example, an ashing process. Copper films 90 in which the ratio of Cu:O is higher than that of Cu₂O may be formed by additionally performing a process, for example, a plasma treatment or a treatment with a basic solution containing hydroxide ions, on the sidewall films 90a formed of the second material.

Referring to FIG. 5E, to form a connection member 120c (refer to FIG. 1) formed of a third material between the bump 80 and a wire substrate 130, after coating a first solder layer 120a on an upper surface of the bump 80 and a second solder layer 120b on a lower surface of the wire substrate 130, the first solder layer 120a and the second solder layer 120b are reflowed and compressed to form the connection member 120c. Next, a space between a semiconductor substrate 20 and the wire substrate 130 is filled with an underfill resin 150 (refer to FIG. 1).

According to some embodiments of the present inventive concept, the second material may be selected so that a wetting angle between the first material and the third material is greater than that between the second material and the third material. In particular, the wetting angle between the first material and the third material may be smaller than 90°, and the wetting angle between the second material and the third material may be greater than 90°.

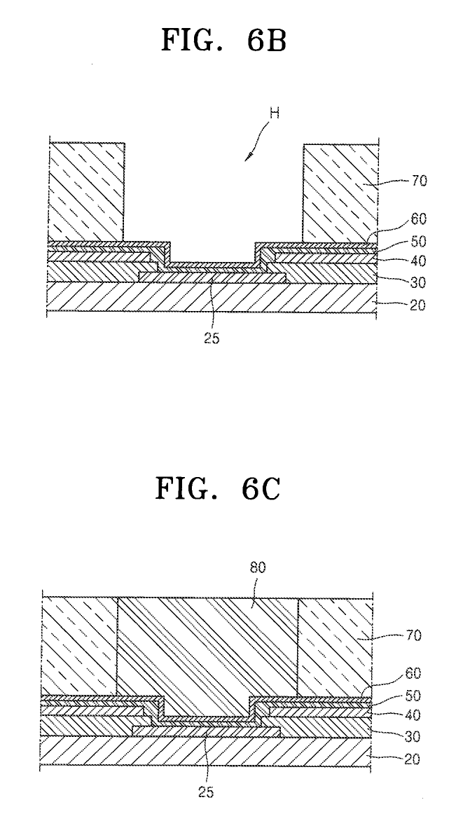

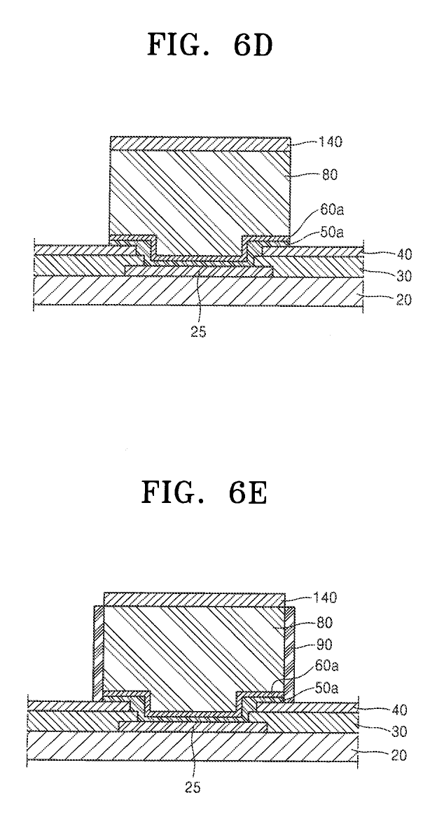

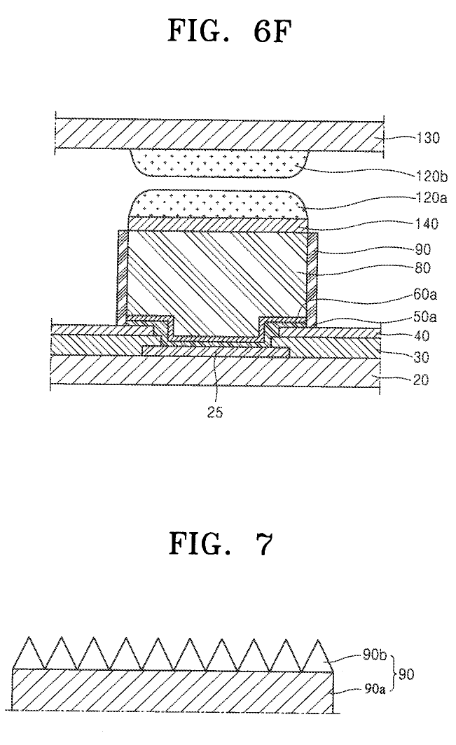

FIGS. 6A and 6F are cross-sectional views illustrating a method of fabricating the semiconductor device 200 of FIG. 2, according to another embodiment of the present inventive concept.

Referring to FIG. 6A, an electrode pad 25 is formed on an upper surface of a semiconductor substrate 20 using Al. A first protective film 30 and/or a second protective film 40 that form an opening H to expose the electrode pad 25 may further be formed on the semiconductor substrate 20. The first protective film 30 and/or the second protective film 40 may be formed of an oxide film and/or a nitride film, respectively.

First and second intermediate connection films 50 and 60 formed of Ti and/or Cu may be formed on the electrode pad 25 so as to be interposed between the electrode pad 25 and the bump 80 (shown in FIG. 6C). The first intermediate connection film 50 may be formed of Ti and the second intermediate connection film 60 may be formed of Cu, however, the present inventive concept is not limited thereto.

Referring to FIG. 6B, a mask pattern 70 having an opening H is formed on a location corresponding to the electrode pad 25. The mask pattern 70 may be a photoresist pattern.

Referring to FIG. 6C, the bump 80 is formed by filling the opening H with a conductive first material. The opening H is defined by inner sidewalls of the mask pattern 70. As an example, the conductive first material may include Cu. The bump 80 can be formed by electroplating and/or electroless plating. However, the bump 80 may be formed using a conventional method of forming a metal film (for example, a physical or chemical vapor deposition method) instead of the plating method. The bump 80 may have a pillar shape.

Referring to FIG. 6D, a top film 140 is formed on an upper surface of the bump 80 using a fourth material. If the first material is Cu, the fourth material may be Au. After removing the mask pattern 70 by, for example, ashing, a second intermediate connection film pattern 60a and a first intermediate connection film pattern 50a are formed by respectively etching the second intermediate connection film 60 and the first intermediate connection film 50 using the bump 80 as a mask. According to some embodiments, the sequence of the removing of the mask pattern 70 and the forming of the top film 140 using the fourth material may be reversed.

Referring to FIG. 6E, sidewall films 90 are formed on sidewalls of the bump 80 using a second material. If the bump 80 is formed of Cu, the sidewall films 90 may be copper oxide films.

Referring to FIG. 6F, to form a connection member 120c (refer to FIG. 2) formed of a third material between the bump 80 and a wire substrate 130, a first solder layer 120a is coated on an upper surface of the bump 80 and a second solder layer 120b is coated on a lower surface of the wire substrate 130. Afterwards, the first solder layer 120a and the second solder layer 120b are reflowed and compressed to form the connection member 120c. Next, a space between the semiconductor substrate 20 and the wire substrate 130 is filled with an underfill resin 150 (refer to FIG. 2).

The second material may be selected so that a wetting angle between the second material and the third material is greater than that between the fourth material and the third material. In particular, the wetting angle between the fourth material and the third material may be smaller than 90°, and the wetting angle between the second material and the third material may be greater than 90°. For example, if the fourth material includes Au and the third material includes solder, the second material may be a copper oxide.

A method of forming copper oxide films 90 on sidewalls of the bump 80 will not repeated here because this method is similar to the method of forming copper oxide films 90 on the sidewalls of the bump 80 described with reference to FIGS. 4A through 4F.

In a semiconductor device and a method of fabricating the semiconductor device according to the present inventive concept, a material film having a large wetting angle with solder is formed on sidewalls of a bump, and accordingly, the solder is not formed on the sidewalls of the bump. Consequently, a stand-off height of the bump can be maintained. Accordingly, the semiconductor device can have a high resistance to external impacts, and an underfill resin can easily be filled in a space between a semiconductor substrate and a wire substrate.

In particular, since a copper oxide film, in which the ratio of Cu:O having a needle shape is greater than that of Cu₂O, is formed on sidewalls of a bump, a bonding force between the underfill resin and the copper oxide film is increased, thereby ensuring a stable structure of the semiconductor device.

Also, since the copper oxide film is formed on the sidewalls of the bump, the bump formed of Cu does not contact the underfill resin, thereby preventing corrosion of the bump and an electro-migration phenomenon.

According to an aspect of the present inventive concept, there is provided a method of fabricating a semiconductor device comprising: forming a mask pattern having an opening on a semiconductor substrate, the opening corresponding to an electrode pad formed on the semiconductor substrate; forming a bump on the electrode pad by filling the opening with a conductive first material; forming a sidewall film on sidewalls of the bump using a second material; forming a connection member using a conductive third material between an upper surface of the bump and a wire substrate to electrically connect the bump and the wire substrate; and forming an underfill resin between the wire substrate and the semiconductor substrate.

A wetting angle between the second material and the third material may be greater than that between the first material and the third material.

The first material may comprise Cu, the second material may be a copper oxide in which the ratio of Cu:O is greater than that of Cu₂O, and the third material may be solder.

According to another aspect of the present inventive concept, there is provided a method of fabricating a semiconductor device comprising: forming a mask pattern having an opening on a semiconductor substrate corresponding to an electrode pad formed on the semiconductor substrate; forming a sidewall film using a second material on inner walls of the mask pattern; forming a bump by filling the opening with a conductive first material; removing the mask pattern; forming a connection member using a conductive third material between an upper surface of the bump and a wire substrate to electrically connect the bump and the wire substrate; and forming an underfill resin between the wire substrate and the semiconductor substrate, wherein a wetting angle between the second material and the third material is greater than that between the first material and the third material.

The wetting angle between the first material and the third material may be smaller than 90° and the wetting angle between the second material and the third material may be greater than 90°.

The forming of the bump using the first material may comprise forming a Cu bump by electroplating and/or electroless plating. The forming of the thin film using the second material may comprise forming a thin film using a copper oxide film. In this case, the forming of the connection member between the upper surface of the bump and the wire substrate using the conductive third material may comprise: coating a first solder layer on the upper surface of the bump; coating a second solder layer on a lower surface of the wire substrate; and forming the connection member by reflowing and compressing the first solder layer and the second solder layer.

The forming of the thin film using a copper oxide film may comprise plating the copper oxide film or forming the copper oxide film by oxidizing the bump.

The forming of the copper oxide film by oxidizing the bump may comprise processing the bump with plasma in an oxygen atmosphere.

The forming of the thin film using the copper oxide film by oxidizing the bump may comprise: softly etching the surface of the bump in an atmosphere containing H₂SO₄ and H₂O₂ or an atmosphere containing NaPS; and forming the copper oxide film to have a ratio of Cu:O greater than that of Cu₂O on the bump by treating the bump using a basic solution containing hydroxide ions. The method may further comprise reducing the copper oxide film using Morpholine Borane after the forming of the copper oxide film.

The method may further comprise forming a top film formed of a fourth material on an upper surface of the bump prior to forming the third material, wherein a wetting angle between the second material and the third material is greater than that between the third material and the fourth material.

The wetting angle between the third material and the fourth material may be smaller than 90° and the wetting angle between the second material and the third material may be greater than 90°.

According to an aspect of the present inventive concept, there is provided a semiconductor device comprising: a bump formed using a conductive first material on an electrode pad on a semiconductor substrate; a sidewall film formed using a second material on sidewalls of the bump; a connection member formed using a conductive third material between an upper surface of the bump and a wire substrate to electrically connect the bump to the wire substrate; and an underfill resin disposed between the wire substrate and the semiconductor substrate, wherein the a wetting angle between the second material and the third material is greater than that between the first material and the third material.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims.

1. A method of fabricating a semiconductor device comprising:
forming a mask pattern defining an opening on a semiconductor substrate, the opening corresponding to an electrode pad formed on the semiconductor substrate;
forming a bump on the electrode pad by filling the opening defined by the mask pattern with a first material;
removing the mask pattern;
forming a sidewall film on sidewalls of the bump using a second material;
forming a connection member using a third material between an upper surface of the bump and a wire substrate so as to electrically connect the bump and the wire substrate; and
forming an underfill resin between the wire substrate and the semiconductor substrate,
wherein a wetting angle between the second material and the third material is greater than a wetting angle between the first material and the third material.

2. The method of claim 1, further comprising forming a top film using a fourth material on an upper surface of the bump prior to forming the third material, wherein the wetting angle between the second material and the third material is greater than a wetting angle between the third material and the fourth material.

3. The method of claim 2, wherein the wetting angle between the third material and the fourth material is less than 90° and the wetting angle between the second material and the third material is greater than 90°.

4. The method of claim 1, wherein the wetting angle between the first material and the third material is less than 90° and the wetting angle between the second material and the third material is greater than 90°.

5. The method of claim 1, wherein the forming of the bump using the first material comprises forming a copper (Cu) bump by at least one of electroplating and electroless plating.

6. The method of claim 5, wherein the forming of the connection member between the upper surface of the bump and the wire substrate using the third material comprises:
coating a first solder layer on the upper surface of the bump;
coating a second solder layer on a lower surface of the wire substrate; and
forming the connection member by reflowing and compressing the first solder layer and the second solder layer.

7. The method of claim 6, further comprising forming a top film using gold (Au) on the upper surface of the bump prior to forming the connection member using the third material, wherein the wetting angle between the second material and the third material is greater than a wetting angle between the third material and Au.

8. The method of claim 5, wherein the forming of the sidewall film using the second material comprises forming a copper oxide film.

9. The method of claim 8, wherein the forming of the sidewall film using a copper oxide film comprises plating the copper oxide film.

10. The method of claim 8, wherein the forming of the sidewall film using a copper oxide film comprises oxidizing the bump.

11. The method of claim 10, wherein oxidizing the bump comprises processing the bump with plasma in an oxygen atmosphere.

12. The method of claim 10, wherein oxidizing the bump comprises:
etching the surface of the bump in an atmosphere containing H₂SO₄ and H₂O₂ or an atmosphere containing sodium peroxosulphate (NaPS); and
treating the bump using a basic solution containing hydroxide ions such that the copper oxide film has a ratio of Cu:O greater than that of Cu₂O.

13. The method of claim 12, further comprising reducing the copper oxide film using Morpholine Borane after treating the bump.

14. A method of fabricating a semiconductor device comprising:
forming a mask pattern defining an opening on a semiconductor substrate, the opening corresponding to an electrode pad formed on the semiconductor substrate;
forming a sidewall film using a second material on inner walls of the opening;
forming a bump by filling the opening with a first material;
removing the mask pattern;
forming a connection member between an upper surface of the bump and a wire substrate using a third material to electrically connect the bump and the wire substrate; and
forming an underfill resin between the wire substrate and the semiconductor substrate,
wherein a wetting angle between the second material and the third material is greater than a wetting angle between the first material and the third material.

15. The method of claim 14, wherein forming the bump using the first material comprises forming a copper (Cu) bump using at least one of electroplating and electroless plating, and wherein forming the sidewall film using the second material comprises forming a Cu oxide film using at least one of electroplating and electroless plating.

16. The method of claim 15, wherein forming the connection member between the upper surface of the bump and the wire substrate using the conductive third material comprises:
coating a first solder layer on the upper surface of the bump;
coating a second solder layer on a lower surface of the wire substrate; and
forming the connection member by reflowing and compressing the first solder layer and the second solder layer.

17. The method of claim 16, further comprising forming a top film using gold (Au) on the upper surface of the bump prior to forming the connection member using the third material, wherein the wetting angle between the second material and the third material is greater than a wetting angle between the third material and Au.

18. A method of fabricating a semiconductor device comprising:
forming a mask pattern defining an opening on a semiconductor substrate, the opening corresponding to an electrode pad formed on the semiconductor substrate;
forming a bump on the electrode pad by filling the opening with a first material;
removing the mask pattern;
forming a sidewall film on sidewalls of the bump using a second material;
forming a top film on an upper surface of the bump using a fourth material; and
forming a connection member between the top film and a wire substrate using a third material so as to electrically connect the bump and the wire substrate;
wherein a wetting angle between the second material and the third material is greater than a wetting angle between the fourth material and the third material.

19. The method of claim 18, wherein forming the mask pattern comprises forming the mask pattern on at least one of a first protective film and a second protective film disposed on the substrate.

20. The method of claim 18, further comprising:
forming a first intermediate connection film on the electrode pad; and
forming a second intermediate connection film on the first intermediate connection film such that the first and second intermediate connection films are disposed between the electrode pad and the bump.
